(19) United States
(12) Patent Application Publication
(10) Pub. No.: US 2013/0200444 A1
(43) Pub. Date: Aug. 8, 2013

(54) SCHOTTKY BARRIER FIELD EFFECT TRANSISTOR WITH CARBON-CONTAINING INSULATION LAYER AND METHOD FOR FABRICATING THE SAME

(71) Applicants: Wei Wang, Beijing (CN); Jing Wang, Beijing (CN); Mei Zhao, Beijing (CN); Renrong Liang, Beijing (CN)

(72) Inventors: Wei Wang, Beijing (CN); Jing Wang, Beijing (CN); Mei Zhao, Beijing (CN); Renrong Liang, Beijing (CN)

(21) Appl. No.: 13/583,121

(22) PCT Filed: Mar. 22, 2012
(86) PCT No.: PCT/CN12/72838

§ 371 Date: Sep. 6, 2012

(30) Foreign Application Priority Data
Feb. 7, 2012 (CN) 20121002661.2

(51) Int. Cl. H01L 29/78; H01L 21/336

(52) U.S. Cl. 257/288; 438/294; 257/E29.255; 257/E21.409

(57) ABSTRACT

A Schottky barrier field effect transistor with a carbon-containing insulation layer and a method for fabricating the same are provided. The Schottky barrier field effect transistor comprises: a substrate; a gate stack formed on the substrate; a metal source and a metal drain formed in the substrate on both sides of the gate stack respectively; and the carbon-containing insulation layer formed between the substrate and the metal source and between the substrate and the metal drain respectively, in which a material of the carbon-containing insulation layer is organic molecular chains containing an alkyl group.

### CROSS-REFERENCE TO RELATED APPLICATION

This application claims priority to and benefits of Chinese Patent Application Serial No. 201210026661.2, filed with the State Intellectual Property Office of P. R. China on Feb. 7, 2012, the entire content of which is incorporated herein by reference.

### FIELD

The present disclosure relates to semiconductor design and manufacture, and more particularly to a Schottky barrier field effect transistor with a carbon-containing insulation layer and a method for fabricating the same.

### BACKGROUND

With a continuous scaling down of a transistor feature size, a conventional transistor fabrication technology has been increasingly challenged. Compared with a field effect transistor of a conventional structure, a Schottky barrier field effect transistor with a feature size not greater than 30 nm has advantages of low source resistance and low drain resistance, natural abrupt contact, no latch-up effect, etc. However, contacts of Schottky barrier source and drain generally have Fermi level pinning phenomenon, thus limiting source and drain current. One solution of inserting a thin insulation layer between a semiconductor substrate and a metal source and between the semiconductor substrate and a metal drain to block the free states in the metal source and the metal drain from entering the semiconductor substrate may reduce band gaps states induced by the metal, alleviate the Fermi level pinning phenomenon and reduce a Schottky contact barrier height. However, conventionally, the thin insulation layer is generally an ultra-thin film of silicon nitride or other similar materials deposited by a PVD or CVD method which has complicated process and weak repeatability. A small deviation of the film deposition equipment and process may result in a thickness deviation of the insulation layer, which may influence a blocking effect to the free states of metals and may be unfavorable for reduction of the Schottky barrier.

Therefore, it has become a focus to develop an effective blocking insulation structure and an ingredient, and a fast and economic method for fabricating the same which may ensure a film quality and a process stability.

### SUMMARY

The present disclosure is aimed to solve at least one of the above mentioned technical problems, particularly provides a Schottky barrier field effect transistor having a carbon-containing insulation layer and a method for fabricating the same.

According to an aspect of the present disclosure, a Schottky barrier field effect transistor with a carbon-containing insulation layer is provided. The Schottky barrier field effect transistor comprises: a substrate; a gate stack formed on the substrate; a metal source and a metal drain formed in the substrate on both sides of the gate stack respectively; and the carbon-containing insulation layer formed between the substrate and the metal source and between the substrate and the metal drain respectively, in which a material of the carbon-containing insulation layer is organic molecular chains containing an alkyl group.

According to embodiments of the present disclosure, the Schottky barrier field effect transistor has the carbon-containing insulation layer, so that the Fermi level pinning phenomenon may be alleviated and the Schottky contact barrier height may be effectively reduced.

In one embodiment, the material of the carbon-containing insulation layer contains straight-chain or branched alkyl varied from dodecyl to eicosyl.

In one embodiment, the carbon-containing insulation layer is an organic monomolecular layer.

In one embodiment, a thickness of the carbon-containing insulation layer is within a range from 0.3 nm to 5 nm.

In one embodiment, the Schottky barrier field effect transistor further comprises: an isolation layer formed on the metal source, the metal drain and the gate stack; and metallic interconnections formed on the isolation layer, in which two contact holes penetrate through the isolation layer and contact with the metal source and the metal drain respectively, and the metallic interconnections are connected to the metal source and the metal drain via the two contact holes respectively.

According to another aspect of the present disclosure, a method for fabricating a Schottky barrier field effect transistor with a carbon-containing insulation layer is provided. The method comprises steps of:

S1: providing a substrate;

S2: forming a gate stack on the substrate;

S3: forming a source recess and a drain recess by self-aligning etching the substrate using the gate stack as a mask to obtain a patterned wafer;

S4: forming the carbon-containing insulation layer in the source recess and in the drain recess respectively; and

S5: forming a metal source and a metal drain on the carbon-containing insulation layer in the source recess and the drain recess respectively.

The carbon-containing insulation layer fabricated by the method according to embodiments of the present disclosure may alleviate the Fermi level pinning phenomenon and effectively reduce the Schottky contact barrier height. In addition, the method for fabricating the Schottky barrier field effect transistor with the carbon-containing insulation layer according to embodiments of the present disclosure is simple and has low fabrication cost.

In one preferred embodiment, Step S4 of forming the carbon-containing insulation layer may comprise steps of:

S41: rinsing the patterned wafer to remove organic contaminants on a surface of the patterned wafer formed in Step S3;

S42: preparing a constant temperature environment;

S43: immersing the patterned wafer in a liquid organic matter and maintaining the patterned wafer under the constant temperature environment for certain time to form the carbon-containing insulation layer in the source recess and in the drain recess respectively; and

S44: rinsing the patterned wafer to remove a remaining organic matter.

The method for fabricating the carbon-containing insulation layer is simple and fast and has good process stability. The carbon-containing insulation layer formed by the method is substantially uniform in thickness, and may effectively block the free states of metals from entering the semiconductor substrate, thus reducing the Schottky contact barrier height.

In one embodiment, the organic matter is a non-single bond electron acceptor and is in a liquid state under the constant temperature environment.

In one embodiment, the constant temperature environment is an environment of a water bath or an oil bath.

In one embodiment, a temperature of the oil bath is within a range from 100 degree Celsius to 200 degree Celsius, and a time for which the patterned wafer is maintained in the oil bath is within a range from 60 minutes to 180 minutes.

In one embodiment, a temperature of the water bath is within a range from 60 degree Celsius to 100 degree Celsius, and a time for which the patterned wafer is maintained in the water bath is within a range from 60 minutes to 180 minutes.

In one embodiment, a material of the carbon-containing insulation layer is organic molecular chains containing an alkyl group.

In one embodiment, the material of the carbon-containing insulation layer comprises straight-chain or branched alkyl varied from dodecyl to eicosyl.

In one embodiment, the carbon-containing insulation layer is an organic monomolecular layer.

In one embodiment, a thickness of the carbon-containing insulation layer is within a range from 0.3 nm to 5 nm.

In one embodiment, after step S5, the method further comprises steps of: S6: forming an isolation layer on the metal source, the metal drain and the gate stack and penetrating through the isolation layer to form two contact holes contacting with the metal source and the metal drain respectively; and S7: forming metallic interconnections on the isolation layer, in which the metallic interconnections are connected to the metal source and the metal drain via the two contact holes respectively.

Additional aspects and advantages of the embodiments of the present disclosure will be given in part in the following descriptions, become apparent in part from the following descriptions, or be learned from the practice of the embodiments of the present disclosure.

### BRIEF DESCRIPTION OF THE DRAWINGS

These and other aspects and advantages of the disclosure will become apparent and more readily appreciated from the following descriptions taken in conjunction with the drawings in which:

FIGS. 1-6 are cross-sectional diagrams of intermediate statuses of a Schottky barrier field effect transistor with a carbon-containing insulation layer formed during a process of a method for fabricating the Schottky barrier field effect transistor with the carbon-containing insulation layer according to an embodiment of the present disclosure; and

FIG. 7 is a cross-sectional view of a Schottky barrier field effect transistor with a carbon-containing insulation layer according to a preferred embodiment of the present disclosure.

### REFERENCE NUMBERS

1 a substrate; 2 a gate stack; 3 a carbon-containing insulation layer; 4 a metal source; 5 a metal drain; 6 a side wall; 7 an isolation layer; 8 metallic interconnections.

### DETAILED DESCRIPTION

Embodiments of the present disclosure will be described in detail in the following descriptions, examples of which are shown in the accompanying drawings, in which the same or similar elements and elements having same or similar functions are denoted by like reference numerals throughout the descriptions. The embodiments described herein with reference to the accompanying drawings are explanatory and illustrative, which are used to generally understand the present disclosure. The embodiments shall not be construed to limit the present disclosure.

It is to be understood that phraseology and terminology used herein with reference to device or element orientation (such as, terms like “longitudinal”, “lateral”, “front”, “rear”, “right”, “left”, “lower”, “upper”, “horizontal”, “vertical”, “above”, “below”, “up”, “top”, “bottom” as well as derivative thereof such as “horizontally”, “downwardly”, “upwardly”, etc.) are only used to simplify description of the present invention, and do not alone indicate or imply that the device or element referred to must have or operated in a particular orientation.

Terms concerning attachments, coupling and the like, such as “connected” and “interconnected”, refer to a relationship in which structures are secured or attached to one another either directly or indirectly through intervening structures, as well as both movable or rigid attachments or relationships, unless expressly described otherwise.

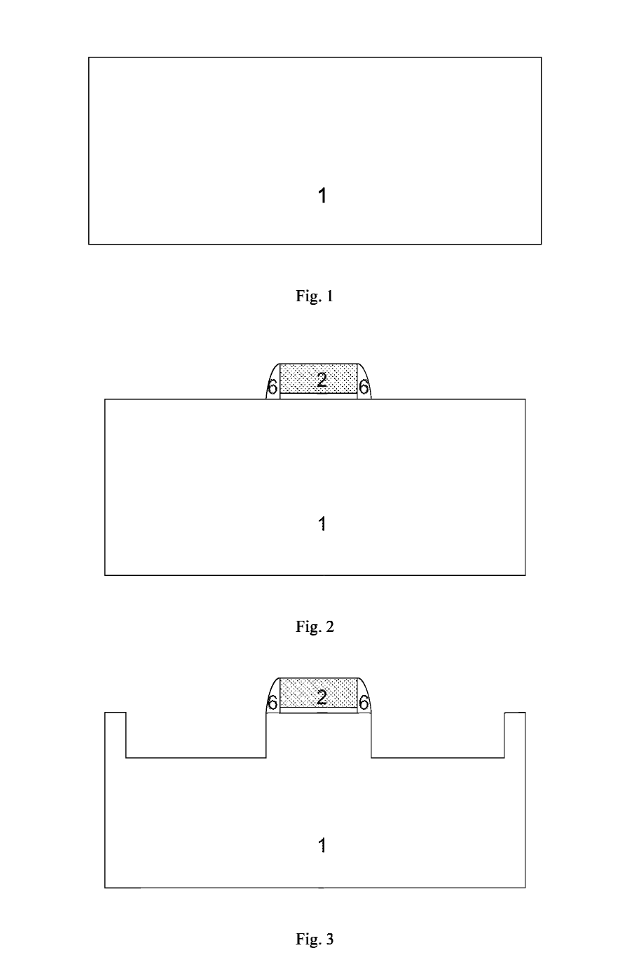

FIGS. 1-6 are cross-sectional diagrams of intermediate statuses of a Schottky barrier field effect transistor with a carbon-containing insulation layer formed during a process of a method for fabricating the Schottky barrier field effect transistor with the carbon-containing insulation layer according to an embodiment of the present disclosure. It should be noted that a size of each region shown in the drawings is exemplary, and the particular size of each region may be designed according to requirements for device parameters. As shown in FIG. 6, the Schottky barrier field effect transistor with the carbon-containing insulation layer comprises a substrate 1. The material of the substrate 1 may be any material for fabricating a Schottky barrier field effect transistor, including, but not limited to, Si, Ge, SiGe, group III-V materials, and group II-VI materials. A gate stack 2 is formed on the substrate 1. The gate stack 2 may comprise a gate dielectric layer and a gate. The gate dielectric layer may include, but is not limited to, a silicon dioxide dielectric layer or a high-k gate dielectric layer. The gate may include, but is not limited to, a metal gate. Certainly, a dielectric layer of other oxides and a polycrystalline silicon gate may also be used, which should also fall within the scope of the present disclosure. In one embodiment, a side wall 6 of one or more layers may be formed on both sides of the gate stack 2. A material of the side wall 6 may include, but is not limited to, silicon dioxide or silicon oxynitride.

A metal source 4 and a metal drain 5 are formed in the substrate 1 on both sides of the gate stack 2 respectively. Materials of the metal source 4 and the metal drain 5 may include, but are not limited to, Al, Cu, Pt, Ni, W, Er, Ti, Yb, other conventional metals, or other rare earth metals. The carbon-containing insulation layer 3 is formed between the substrate 1 and the metal source 4 and between the substrate 1 and the metal drain 5 respectively. A material of the carbon-containing insulation layer 3 is any organic molecular chain containing an alkyl group, including, but not limited to, straight-chain or branched alkyl varied from dodecyl to eicosyl. A thickness of the carbon-containing insulation layer 3 may vary with materials of the carbon-containing insulation layer 3, the metal source 4 and the metal drain 5. In one embodiment, the carbon-containing insulation layer 3 may be an organic monomolecular layer with a thickness ranging from 0.3 nm to 5 nm. In one preferred embodiment, the carbon-containing insulation layer 3 may be a 1-octadecyl layer with a thickness of 2.7 nm.

According to an embodiment of the present disclosure, the carbon-containing insulation layer 3 may block the free states of metals in the metal source 4 and the metal drain 5 from entering the semiconductor substrate, so that the Fermi level pinning phenomenon may be alleviated and the Schottky contact barrier height may be effectively reduced.

In one preferred embodiment, an isolation layer 7 is formed on the metal source 4, the metal drain 5 and the gate stack 2. A material of the isolation layer 7 may include, but is not limited to, silicon dioxide or silicon oxynitride. Two contact holes penetrate through the isolation layer 7 and contact with the metal source 4 and the metal drain 5 respectively. Metallic interconnections 8, which are formed on the isolation layer 7, are connected to the metal source 4 and the metal drain 5 via the two contact holes respectively. In this embodiment, positions of the metal source 4 and the metal drain 5 may interchange with each other.

In order to better understand the structure according to an embodiment of the present disclosure, a method for forming the structure described above is also provided. It should be noted that the structure may be fabricated through various technologies, such as different types of product lines or different processes. However, if the structures fabricated through various technologies have substantially the same structure and technical effects as those of the present disclosure, they should be within the scope of the present disclosure. In order to better understand the present disclosure, the method for forming the structure of the present disclosure described above will be described in detail below. Moreover, it should be noted that the following steps are described only for exemplary and/or illustration purpose rather than for limitations. Other technologies may be adopted by those skilled in the art to form the structure of the present disclosure described above.

In order to form the structure shown in FIG. 6, an embodiment of the present disclosure provides a method for fabricating the Schottky barrier field effect transistor with the carbon-containing insulation layer. The method comprises the following steps.

Step S1, the substrate 1 is provided.

Step S2, the gate stack 2 is formed on the substrate 1.

Step S3, a source recess and a drain recess are formed by self-aligning etching the substrate 1 using the gate stack 2 as a mask to obtain a patterned wafer.

Step S4, the carbon-containing insulation layer 3 is formed in the source recess and in the drain recess respectively.

Step S5, the metal source 4 and the metal drain 5 are formed on the carbon-containing insulation layer 3 in the source recess and the drain recess respectively.

The carbon-containing insulation layer fabricated by the method according to embodiments of the present disclosure may alleviate the Fermi level pinning phenomenon and effectively reduce the Schottky contact barrier height. In addition, the method for fabricating the Schottky barrier field effect transistor with the carbon-containing insulation layer according to embodiments of the present disclosure is simple and has low fabrication cost.

After the Step S2, the side wall 6 of one or more layers may be formed on both sides of the gate stack 2. The material of the side wall 6 may include, but is not limited to, silicon dioxide or silicon oxynitride. The step S4 of forming the carbon-containing insulation layer 3 may comprise the following steps.

Step S41, the patterned wafer is rinsed to remove organic contaminants on a surface of the patterned wafer formed in Step S3.

Step S42, a constant temperature environment is prepared.

Step S43, the patterned wafer is immersed in a liquid organic matter and maintained under the constant temperature environment for certain time to form the carbon-containing insulation layer 3 in the source recess and in the drain recess respectively. The organic matter is a non-single bond electron acceptor and is in a liquid state under the constant temperature environment.

Step S44, the patterned wafer is rinsed to remove a remaining organic matter.

The method for fabricating the carbon-containing insulation layer is simple and fast and has good process stability. The carbon-containing insulation layer formed by the method is substantially uniform in thickness, and may effectively block the free states of metals from entering the semiconductor substrate, thus reducing the Schottky contact barrier height.

After the step S5, the method may further comprise the following steps.

Step S6, the isolation layer 7 is formed on the metal source 4, the metal drain 5 and the gate stack 2, and the isolation layer 7 is penetrated through to form two contact holes contacting with the metal source 4 and the metal drain 5 respectively.

Step S7, metallic interconnections 8 are formed on the isolation layer 7. The metallic interconnections 8 are connected to the metal source 4 and the metal drain 5 via the two contact holes respectively.

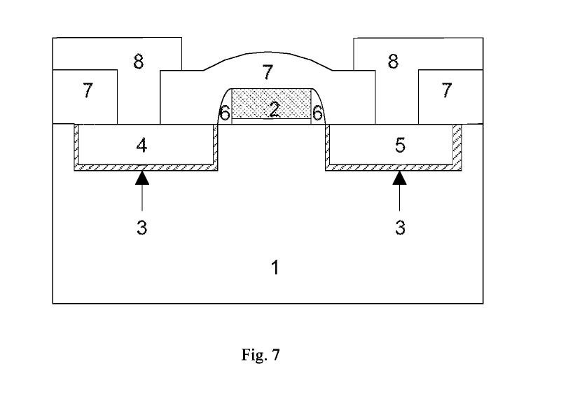

FIG. 7 is a cross-sectional view of a Schottky barrier field effect transistor with a carbon-containing insulation layer according to a preferred embodiment of the present disclosure.

The method for fabricating the Schottky barrier field effect transistor with the carbon-containing insulation layer will be described below with reference to FIGS. 1-7. The method comprises the following steps.

Step 1, as shown in FIG. 1, the substrate 1 is provided. In this embodiment, the material of the substrate 1 may be Si, Ge or SiGe.

Step 2, as shown in FIG. 2, the gate stack 2 is formed on the substrate 1 and the side wall 6 of one or more layers is formed on both sides of the gate stack 2. In this embodiment, the gate stack 2 may comprise a gate dielectric layer and a gate. The gate dielectric layer may include, but is not limited to, a silicon dioxide dielectric layer or a high-k gate dielectric layer. The gate may include, but is not limited to, a metal gate. Certainly, a dielectric layer of other oxides and a polycrystalline silicon gate may also be used, which should also fall within the scope of the present disclosure. The material of the side wall 6 may include, but is not limited to, silicon dioxide or silicon oxynitride.

Step 3, as shown in FIG. 3, the source recess and the drain recess are formed by self-aligning etching the substrate 1 using the gate stack 2 as a mask to obtain a patterned wafer. It should be noted that shapes of the source recess and the drain recess shown in FIG. 3 are merely exemplary, and any shape meeting requirements may be used by those skilled in the art, which may be within the scope of the present disclosure.

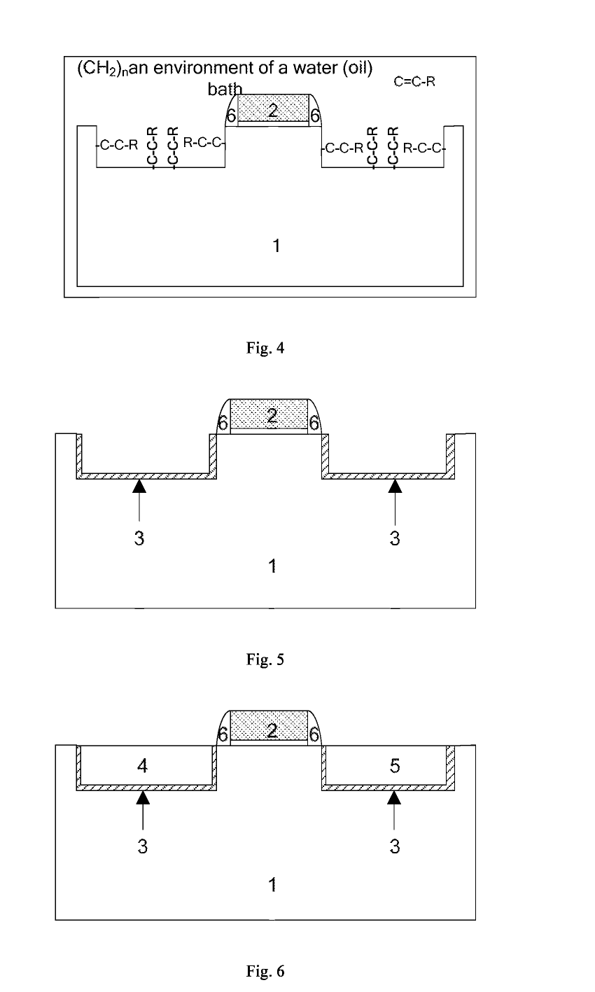

Step 4, as shown in FIG. 4, the carbon-containing insulation layer 3 is formed in the source recess and in the drain recess respectively. Firstly, the patterned wafer is rinsed to remove organic contaminants on a surface of the patterned wafer formed in Step 3. Secondly, a constant temperature environment is prepared. In this embodiment, the constant temperature environment is an environment of a water bath or an oil bath. Thirdly, the patterned wafer is immersed in a liquid organic matter and maintained under the constant temperature environment for certain time to form the carbon-containing insulation layer 3 in the source recess and in the drain recess respectively. The organic matter is a non-single bond electron acceptor and is in a liquid state under the constant temperature environment. Fourthly, the patterned wafer is rinsed to remove the remaining organic matter. Consequently, the carbon-containing insulation layer 3 is formed, as shown in FIG. 5. In one preferred embodiment, the liquid organic matter may be 1-octadecylene. In one embodiment, if an oil bath is used, a temperature of the oil bath is within a range from 100 degree Celsius to 200 degree Celsius, and a time for which the patterned wafer is maintained in the oil bath is within a range from 60 minutes to 180 minutes. More preferably, the temperature of the oil bath is 180 degree Celsius, and the time for which the patterned wafer is maintained in the oil bath is 120 minutes. In another embodiment, if the liquid organic matter is 1-octadecylene and a water bath is used, a temperature of the water bath is within a range from 60 degree Celsius to 100 degree Celsius, and a time for which the patterned wafer is maintained in the water bath is within a range from 60 minutes to 180 minutes. More preferably, the temperature of the water bath is 80 degree Celsius, and the time for which the patterned wafer is maintained in the water bath is 150 minutes. The material of the carbon-containing insulation layer 3 is any organic molecular chain containing an alkyl group, including, but not limited to, straight-chain or branched alkyl varied from dodecyl to eicosyl. The thickness of the carbon-containing insulation layer 3 may vary with materials of the carbon-containing insulation layer 3, the metal source 4 and the metal drain 5. In one embodiment, the carbon-containing insulation layer 3 may be an organic monomolecular layer with a thickness ranging from 0.3 nm to 5 nm. In one preferred embodiment, the carbon-containing insulation layer 3 may be a 1-octadecyl layer with a thickness of 2.7 nm.

Step 5, as shown in FIG. 6, the metal source 4 and the metal drain 5 are formed on the carbon-containing insulation layer 3 in the source recess and the drain recess respectively.

Step 6, as shown in FIG. 7, the isolation layer 7 is formed on the metal source 4, the metal drain 5 and the gate stack 2. The material of the isolation layer 7 may include, but is not limited to, silicon dioxide or silicon oxynitride. The isolation layer 7 is penetrated through to form two contact holes contacting with the metal source 4 and the metal drain 5 respectively. Then, the metallic interconnections 8 are formed on the isolation layer 7. The metallic interconnections 8 are connected to the metal source 4 and the metal drain 5 via the two contact holes respectively.

The carbon-containing insulation layer fabricated by the method according to embodiments of the present disclosure may alleviate the Fermi level pinning phenomenon and effectively reduce the Schottky contact barrier height. In addition, the method for fabricating the Schottky barrier field effect transistor with the carbon-containing insulation layer according to embodiments of the present disclosure is simple and has good process stability and low fabrication cost.

Reference throughout this specification to “an embodiment”, “some embodiments”, “one embodiment”, “an example”, “a specific examples”, or “some examples” means that a particular feature, structure, material, or characteristic described in connection with the embodiment or example is included in at least one embodiment or example of the disclosure. Thus, the appearances of the phrases such as “in some embodiments”, “in one embodiment”, “in an embodiment”, “an example”, “a specific examples”, or “some examples” in various places throughout this specification are not necessarily referring to the same embodiment or example of the disclosure. Furthermore, the particular features, structures, materials, or characteristics may be combined in any suitable manner in one or more embodiments or examples.

Although explanatory embodiments have been shown and described, it would be appreciated by those skilled in the art that changes, alternatives, and modifications all falling into the scope of the claims and their equivalents may be made in the embodiments without departing from spirit and principles of the disclosure.

1. A Schottky barrier field effect transistor with a carbon-containing insulation layer, comprising:
a substrate;
a gate stack formed on the substrate;
a metal source and a metal drain formed in the substrate on both sides of the gate stack respectively; and
the carbon-containing insulation layer formed between the substrate and the metal source and between the substrate and the metal drain respectively, wherein a material of the carbon-containing insulation layer is organic molecular chains containing an alkyl group.

2. The Schottky barrier field effect transistor according to claim 1, wherein the material of the carbon-containing insulation layer contains straight-chain or branched alkyl varied from dodecyl to eicosyl.

3. The Schottky barrier field effect transistor according to claim 1, wherein the carbon-containing insulation layer is an organic monomolecular layer.

4. The Schottky barrier field effect transistor according to claim 3, wherein a thickness of the carbon-containing insulation layer is within a range from 0.3 nm to 5 nm.

5. The Schottky barrier field effect transistor according to claim 1, further comprising:
an isolation layer formed on the metal source, the metal drain and the gate stack; and
metallic interconnections formed on the isolation layer,
wherein two contact holes penetrate through the isolation layer and contact with the metal source and the metal drain respectively, and the metallic interconnections are connected to the metal source and the metal drain via the two contact holes respectively.

6. A method for fabricating a Schottky barrier field effect transistor with a carbon-containing insulation layer, comprising steps of:
S1: providing a substrate;
S2: forming a gate stack on the substrate;
S3: forming a source recess and a drain recess by self-aligning etching the substrate using the gate stack as a mask to obtain a patterned wafer;
S4: forming the carbon-containing insulation layer in the source recess and in the drain recess respectively; and
S5: forming a metal source and a metal drain on the carbon-containing insulation layer in the source recess and the drain recess respectively.

7. The method according to claim 6, wherein Step S4 comprises steps of:
S41: rinsing the patterned wafer to remove organic contaminants on a surface of the patterned wafer formed in Step S3;
S42: preparing a constant temperature environment;
S43: immersing the patterned wafer in a liquid organic matter and maintaining the patterned wafer under the constant temperature environment for certain time to form the carbon-containing insulation layer in the source recess and in the drain recess respectively; and
S44: rinsing the patterned wafer to remove a remaining organic matter.

8. The method according to claim 7, wherein the organic matter is a non-single bond electron acceptor and is in a liquid state under the constant temperature environment.

9. The method according to claim 7, wherein the constant temperature environment is an environment of a water bath or an oil bath.

10. The method according to claim 9, wherein a temperature of the oil bath is within a range from 100 degree Celsius to 200 degree Celsius, and a time for which the patterned wafer is maintained in the oil bath is within a range from 60 minutes to 180 minutes.

11. The method according to claim 9, wherein a temperature of the water bath is within a range from 60 degree Celsius to 100 degree Celsius, and a time for which the patterned wafer is maintained in the water bath is within a range from 60 minutes to 180 minutes.

12. The method according to claim 7, wherein a material of the carbon-containing insulation layer is organic molecular chains containing an alkyl group.

13. The method according to claim 12, wherein the material of the carbon-containing insulation layer comprises straight-chain or branched alkyl varied from dodecyl to eicosyl.

14. The method according to claim 6, wherein the carbon-containing insulation layer is an organic monomolecular layer.

15. The method according to claim 14, wherein a thickness of the carbon-containing insulation layer is within a range from 0.3 nm to 5 nm.

16. The method according to claim 6, after step S5, further comprising steps of:
S6: forming an isolation layer on the metal source, the metal drain and the gate stack and penetrating the isolation layer to form two contact holes contacting with the metal source and the metal drain respectively; and
S7: forming metallic interconnections on the isolation layer, wherein the metallic interconnections are connected to the metal source and the metal drain via the two contact holes respectively.
